(19) United States
(12) Patent Application Publication
(10) Pub. No.: US 2007/0158642 A1
(43) Pub. Date: Jul. 12, 2007

(54) Active electronic devices with nanowire composite components

(75) Inventor: George Gruner, Los Angeles, CA (US)

Correspondence Address: VENABLE LLP, P.O. BOX 34385, WASHINGTON, DC, 20043-9998, US

(73) Assignee: Regents of the University of California, Oakland, CA (US)

(21) Appl. No.: 10/582,407

(22) PCT Filed: Dec. 16, 2004
(86) PCT No.: PCT/US04/43179

§ 371 Date: Jun. 9, 2006

Related U.S. Application Data
(60) Provisional application No. 60/531,285, filed on Dec. 19, 2003.

(51) Int. Cl. H01L 29/08; H01L 29/76

(52) U.S. Cl. 257/40; 257/30; 257/288

(57) ABSTRACT

Active, electrical, electronic and optoelectronic components and structures are fabricated to include composites containing electrically conductive nanostructures as part thereof. These nanostructures include nanowires, nanofibres, nanoribbons, nanoplates or nanotubes as single structures or an assembly of multiple structures. They are composed of carbon or other conductive materials.

Benefit of U.S. Provisional Application 60/531,285, filed Dec. 19, 2003 is claimed.

This application is directed to electrical, electronic and optoelectronic components and structures which include composites containing conducting nanostructures as a part thereof.

### BACKGROUND

Nanostructures are three-dimensional structures where at least one dimension is less than 100 nm. These structures include nanowires, nanofibres, nanoribbons, nanoplates and nanotubes as single structures or an assembly of multiple structures. They are composed of carbon and other materials. When the term nanowires or nano tubes is used herein the disclosure is intended to also include other nanostructures which can be formed into similar acting composites.

Electronic devices, such a resistors, diodes and transistors which include nanowire conductors (not composites) have been fabricated before, as shown in numerous references. (Duan, X. and Lieber. C., Adv. Mat 12, 298 (2000); Adrian Bachtold, Peter Hadley, Takeshi Nakanishi, and Cees Dekker, “Logic Circuits with Carbon Nanotube Transistors” Science, 294, 1317-1320 (2001); Derycke, V.; Martel, R.; Appenzeller, J.; Avouris, Ph.; “Carbon Nanotube Inter- and Intramolecular Logic Gates,” Nano Lett. 1, 453-456 (2001); Ali Javey, Moonsub Shim, and Hongjie Dai.; “Electrical Properties and Devices of Large-Diameter Single-Walled Carbon Nanotubes,” Appl. Phys. Lett, 80, 1064-1066 (2002); R. Martel, T. Schmidt, H. R. Shea, T. Hertel, and Ph. Avouris, “Single- and Multi-wall Carbon Nanotube Field-effect Transistors,” Appl. Phys. Lett., 73, 2447-2449 (1998); Paul L. McEuen, Marc Bockrath, David H. Cobden, Young-Gui Yoon, and Steven G. Louie, “Disorder, Pseudospins, and Backscattering in Carbon Nanotubes,” Phys. Rev. Lett., 83, 5098-5101 (1999); Sander J. Tans, Alwin R. M. Verschueren, Cees Dekker, “Room-temperature Transistor Based on a Single Carbon Nanotube, Nature 393, 49-52 (1998).

It has also been shown that devices formed with carbon nanotube networks can operate as transistor devices. Networks of nanotubes have also been shown to support Field Effect Transistor (FET) operation. (Snow, E. S., Novak, J. P., Campbell, P. M. & Park, D. “Random Networks of Carbon Nanotubes as an Electronic Material”, Applied Physics Letters 82, 2145-2147 (2003); J-C Gabriel, “Large Scale Production of Carbon Nanotube Transistors,” Mat. Res. Soc. Symp. Proc., 776, R. J. Chen et al, “Noncovalent Functionalization of Carbon Nanotubes for Highly Specific Biosensors”, PNAS 100, 49483 (2003); K. Bradley, J-C P Gabriel and G. Gruner, “Flexible Nanotube Electronics” Nano Lett, 3, 1353 (2003); N. P. Armitage, J-C P Gabriel and G. Gruner, “Langmuir-Blodgett Nanotube Films”, J. Appl. Phys. Lett, 95, 6, 3228-3330 (2003)).

Prototypes of memory devices based on carbon nanotube field-effect transistors (NT-FETs) have also been reported. (Cui, J. B.; Sordan, R.; Burghard, M.; Kern, K. Appl. Phys. Lett., 81, 3260-3262 (2002); Radosavljevic', M.; Freitag, M.; Thadani, K. V.; Johnson, A. T. Nano Lett., 2, 761-764 (2002); Fuhrer, M. S.; Kim, B. M.; Du\ddot{}rkop, T.; Brintlinger, T. Nano Lett., 2, 755-759 (2002).

Composites which include nanowires or nanotubes have recently been fabricated and these composites have been demonstrated to be useful as resistors. Chen et al (Chen, R. Ramasubramanian and H. Liu, “Noncovalent Engineering of Carbon Nanotube Surfaces by Rigid, Functional Conjugated Polymers”, J. Am. Chem. Soc., 124 9034-9035 (2002)) reports on the use of a short, rigid functional conjugated polymer (polyaryleneethylene) to coat the surface of nanotubes to render them solublizable in various organic solvents and then dispersing the solublized nanotubes in polymers such as polycarbonate or polystyrene. However, Chen has not shown the use of such composites as active electronic devices. Ramamurthy et al (“Single Walled Carbon Nanotube Composite Electronic Device” 11^{th} Foresight Conference, Oct. 10-12, 2003.) reports on the addition of nanotubes to a conducting polymer (polyanilane) to form conducting composites.

Poly (2-methoxy-5-(2-ethyl-hexyloxy)-1,4-phenylene vinylene) (MEH-PPV), a light sensitive semiconducting polymer (Yu, G.; Gao, J.; Hummelen, J. C.; Wudl, F.; Heeger, A. J. Science, 1995, 270, 1789) has been combined with a semiconductor inorganic nanorod, specifically Cd Se nanorods (Huynh, W. U.; Dittmer, J. J.; Alivisatos, A. P. Science, 295, 2425-2427 (2002)) or with carbon nanotubes (Ago, H.; Petritsch, K.; Shaffer, M. S. P.; Windle, A. H.; Friend, R. H. Adv. Mater, 11, 1281-1285 (1999); Kymakis, E.; Amaratunga, G. A. J. Appl. Phys. Lett., 80, 112-114 (2002) to form photovoltaic devices.

However, no one has demonstrated that composites combining conductive nanostructures with polymers, monomeric organic compounds, inorganic compounds and other materials surrounding the nanostructures can be used as active electronic devices. While composites of nanostructures have been made before, they have not been incorporated into active electronic devices and it has not been shown that if incorporated into active electronic device, they would be operational.

### SUMMARY

Electronic devices such as diodes, field effect transistors, optoelectronic devices, and solar cells can be constructed incorporating composites which include conductive nanowires, carbon nanotubes and polymeric nanofibers dispersed and embedded within a host material and largely surrounded by that second (host) material such as a polymer or any other non-conductive partially conductive or semi-conductive organic or inorganic material.

### BRIEF DESCRIPTION OF THE DRAWINGS

FIG. 1 is a top view of a composite including nanowires incorporating features of the invention.

FIG. 2 is a schematic side view of a field effect transistor incorporating the composite structure of FIG. 1.

FIG. 3 is schematic side view of a diode incorporating two composite channels with different, p-doped and n-doped composites.

FIG. 4 is a tilted side perspective, schematic drawing showing NT-FET incorporating a solution-deposited composite as shown in FIG. 1.

FIG. 5 is a scanning electron microscopy (SEM) image of a PmPV/NT composite deposited on a Si wafer.

FIG. 6 is a graph showing the dependence of source-drain current on the gate voltage for a transistor formed according to the teaching herein.

FIG. 7 is a graph showing the electrical characteristics of an SDS coated nanotube composite transistors with a doped Si/SiO2 substrate gate.

FIG. 8 is a graph showing the source-drain dependence of the current for a SDS coated nanotube composite transistors.

FIG. 9 is a graph showing the electrical characteristics of an SDS coated nanotube composite transistors with liquid gating.

FIG. 10 is a graph showing the source-drain dependence of the current for a SDS coated nanotube composite transistors with liquid gating.

FIG. 11 is a schematic side view of a solar cell incorporating a composite of nanotubes.

FIG. 12 is graph showing the generation of charges in a light activated device which includes a PmPV-nanotube composite exposed to UV light.

### DESCRIPTION

The term “active electronic device” as used herein, refers to a device that includes a source and a drain electrode with a composite material which carries electrical current between the electrodes. The structure may also include a third electrode. The device is distinguished from a simple resistor in that the conductivity of the composite depends on an applied voltage, for example, between the source and the drain (i.e., a diode), a gate voltage (i.e., a transistor) or energy provided such as by an electromagnetic radiation (optoelectronic device), creating a charge to be transferred between components.

Applicant has discovered that active electronic device structures can be constructed of a composite material that incorporates conductive nanostructures, particularly nanowires, nanotubes or nanofibers where the nanowires, nanotubes or nanofibers in the composite act as the conductive/electronic elements of the device and not merely as a structural element. The nanostructure can be present as a random network of nanostructures, aligned or partially aligned individual nanostructures or bundles of individual nanostructures or as a mat of nanostructures. The second material can be selected from a broad range of materials which include, but are not limited to nonconducting, poorly conducting or semiconducting polymers, organic compounds, or inorganic materials such as ceramics. This second material may also be an “active” material in that exposure to an external source, such as light, pressure or heat may cause the rearrangement of the electrons within the composite. Examples include, but are not limited to photoactive polymers and piezoelectric materials. The second material need not comprise a single material but may be a blend of compounds, for example a polymer doped with inorganic materials or metallic ions, or a blend of two or more polymers. A composite is a material that consists of a homogenous, or substantially homogenous or uniform, combination or mixture of two or more components or materials differing in composition or form on a macroscale. The constituents retain their identities in the composite in that they do not dissolve or otherwise merge completely into each other. However, because a first component totally or substantially surrounds a second component they act in concert. While various mixtures can be prepared, the term composite includes, but is not limited to, single nanostructures coated on all sides by an organic or inorganic material, such as a polymer or ceramic coated single fiber, or a bundle of such nanostructures where each component of the bundle is coated, or a mat of nanostructures where each nanostructure in the mat is coated by the second organic or inorganic material. This is distinguished from a sandwich of materials where a layer of a first component is covered by a layer of a second component, such combination being subject to delamination. Normally the components can be physically identified and exhibit an interface between one another.

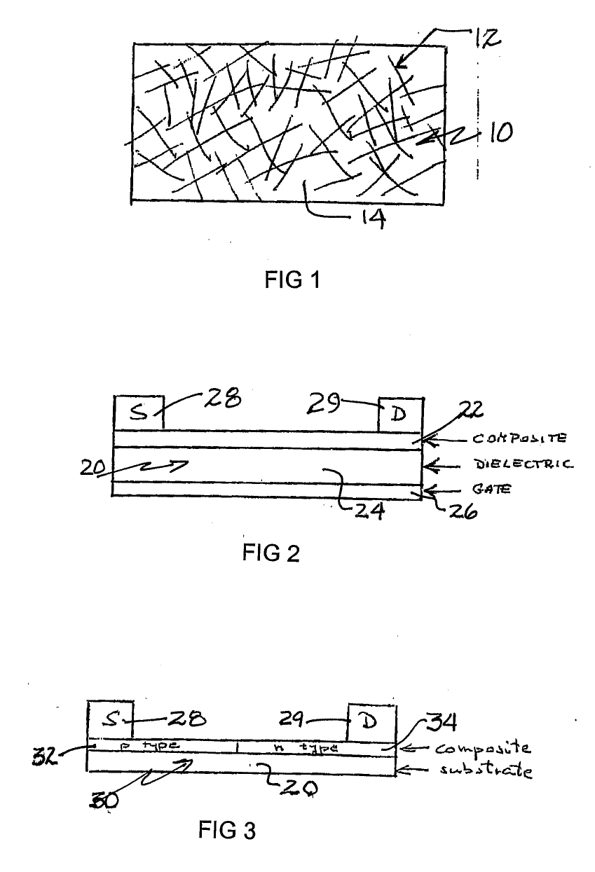

FIG. 1 shows a composite 10, which incorporates features of the invention, including nanostructures 12, for example nanowires. The nanowires 12 are dispersed and embedded within a host material, preferably a non-conductive polymer 14 or any other non-conductive material, such as a chemical coating or a ceramic material. For example, the composite as a whole can provide a conducting channel connecting the source and the drain of an electronic structure. Nano-scale electronic devices including, but not limited to, diodes, field effect transistors, and logic elements are included within the scope of this invention. A typical transistor device 20 architecture is shown in FIG. 2. The field effect transistor device of FIG. 2 includes a nanowire composite conducting channel 22. The substrate 24 (dielectric) can be made of composite or non-conducting polymeric materials. A typical bottom gate 26 configuration is shown but other transistor configurations shown in the literature can also be fabricated. The source 28, drain 29 and the gate 26 can be made of various conducting materials, including common metals, such as copper or silver, conducting polymers, or nanowire composites of various composition, and density.

FIG. 3 shows a typical diode 30 configuration which includes a conducting portion comprising two composites, preferrably with p- and n-type characteristics.

Logic elements can be fabricated by utilizing composite transistors with p-type 32 and n-type 34 characteristics.

Controlling the nanowire density within the composite provides the ability to tailor the operation of the device constructed. For screening of the gate voltage, a dense array of the nanowires is used, in a manner similar to gate voltage screening using metal layers deposited on a device. For a rarified array such screening is not necessary and the array can serve as the source-to-drain conducting channel. For an array involving both metallic and semiconducting wires (such as in case of carbon nanotubes) the conductance of the off state—which can be reached by an application of a positive gate voltage—is dominated by the conductance of the carbon nanotubes. Arrays close too, and on the conducting side of the two dimensional percolation limit have appropriate transistor characteristics. Under such circumstances screening effects are small, but conduction is still provided by the nanostructure network. It is also possible, using a poorly conducting substrate, that a conducting channel can form where part of the current is supported by both the nanotube or nanowire and the substrate.

With appropriate doping and surface modification of the conductive nanostructure composites with both n-type and p-type behavior can be obtained. In particular, FET devices with carbon nanotube conducting channels (NT-FETs), n-type transistor operation in polymer-coated devices and p-type transistor operation, due to absorbed oxygen, have been demonstrated before. In regard to semiconducting nanowires (not in composites), bulk doping can lead to p or n-type operation. A combination and p and n-type transistor devices can lead to a logic element in a fashion similar to logic elements fabricated using standard transistor devices (Star, A.; Han, T.-R.; Joshi, V.; Gruner, G. “Polymer Coatings of Carbon Nanotube Sensors,” Polymer Prep. 44(2), 201; Star (2003), A.; Gabriel, J.-C. P., Bradley, K., Gruner, G. “Electronic Detection of Specific Protein Binding Using Nanotube FET Devices,” Nano Lett., 3, 459-463 (2003))

The conducting and insulating elements of the devices which are attached to, incorporated in, or connect to the nanostructure composites of the invention can be fabricated from various appropriate materials, including metals, conducting and non-conducting polymers or composites. In the latter case, the electrical properties of the constituent materials of the composites, as well as the ratio of the constituents in the composite, determines the conducting properties and electrical characteristics of the components of the device.

As examples, applicant has formed composite carbon nanotube optoelectronic memory devices, nanotube composite transistors, and electronic structures which respond to exposure to light.

The photovoltaic cell is based on the mechanism of induced charge transfer between two layers of materials or between two species interspersed. The most common types of solar cells are based on the photovoltaic effect, which occurs when light falling on a two-layer semiconductor material produces a potential difference, or voltage, between two layers. In addition, the solar cell incorporates a conducting layer that is transparent to sunlight and can act as an electrode. In the photovoltaic or solar cell application described herein the nanostructures are surrounded by a light induced charge transfer medium which, when exposed to light, induces electron transfer to the conducting nanostructures within the composite.

A variety of nanostructure composites can be fabricated and incorporated into the device architecture. The nanostructures include, but are not limited to, small gap oxide semiconducting wires, transition metal-chalcogen molecular nanowires, planar organic molecule based wires, polymeric nanofibres, conductive nanostructures, various single and multiwall nanotube structures, and combinations thereof.

Various standard structural composite fabrication techniques shown in the literature can be utilized to fabricate the composites disclosed herein, the resulting composites having the intended appropriate electrical, structural and other properties.

One example of a method of fabrication of such a device is set forth in Example 1 below which describes photosensitive NT-FET device comprised of a composite of polymer and nanotubes deposited from solution onto Si wafers that included previously patterned electrical contacts. A network of semi-conducting nanotubes connects the source and drain contacts, and the network serves as the channel of a field-effect transistor. The source-drain current was measured as a function of the gate voltage under various conditions of illumination and gate voltage sweep.

### EXAMPLE 1

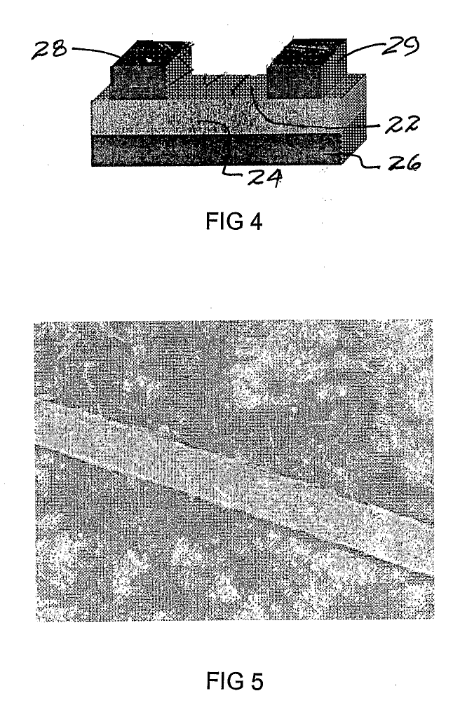

A solution of poly {(m-phenylenevinylene)-co-[(2,5-dioctyloxy-p-phenylene)vinylene]} (PmPV) polymer and carbon nanotubes dispersed in CHCl₃ was prepared. The PmPV polymer was purchased from Aldrich Chemical as a 0.1% polymer solutions in CHCl₃ and used as received. The carbon nano-tubes were grown by chemical vapor deposition, or laser ablation. The solution was then cast on the surface of a Si wafer that was pre-patterned with source (S) 28 and drain (D) 29 electrodes (1 μm wide, 50 μm gap) which were fabricated using standard photolithography techniques. In particular, they comprised a 5 nm bottom layer of Ti, coated with 50 nm thick layer of Au. A typical device is shown schematically in FIG. 4 and an SEM image of the nanotube composite fabricated as described above, deposited on the Si substrate, is shown in FIG. 5.

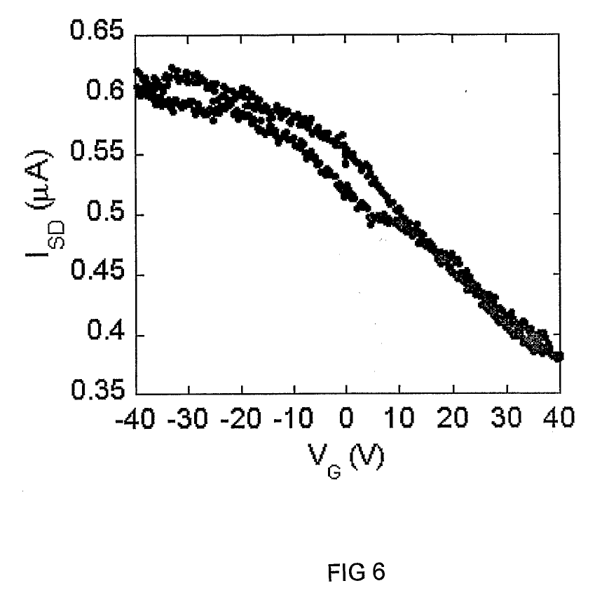

Measurements of the electronic properties of the NT-FET devices, such as current flow between S/D electrodes as a function of applied gate voltage, were conducted using a semiconductor parameter analyzer (Keithley 4200). Gate voltages were swept at 4 Hz. The carbon nanotube packaged devices were assembled inside a benchtop cabinet with either an ultraviolet lamp (UVP, 8 W, UVLMS-38) operating at 365 nm or visible lamp operating at 550 nm. FIG. 6 shows the dependence of the source-drain current on gate voltage. The device recovers nearly as quickly as it responds to light, even at room temperature and at fixed gate voltage. This method of depositing the polymer/nanotube composite directly on top of the patterned electrodes tends to have poor electrical contacts with the source and drain. However, this can be alleviated by improved attachment techniques. As a result, these solution-deposited NT-FETs have high positive threshold voltages and do not turn off completely. This may result from the occasional presence of nanotube bundles containing metallic nanotubes. As a result, relatively large bias voltages may be required. Upon UV illumination there is an increase of ISD, independent of VG (FIG. 6). It has also been found that thin coating, from about 0.01μ to about 10μ are preferred as the electrical charges flow primarily at or near the surface and thicker structures do not provide added electrical performance.

The effect of the particular chemical structure of the polymer PmPV was investigated. A second polymer, regioregular poly(3-octylthiophene-2,5-diyl) (P3OT), obtained from Aldrich Chemical as a 0.2% solution in CHCl₃ was used to fabricate additional NT-FETs. Like PmPV, this polymer has a conjugated aromatic backbone with long alkyl side chains. The two polymers have different absorption maxima, with PmPV absorbing most strongly at 365 nm and P3OT at 550 nm. The presence of carbon nanotubes leads to an insignificant blue shift of the UV-vis spectra.

These comparisons demonstrate the separate roles played by the elements of the assembly. First, photons are absorbed by the polymer layer. These devices operate differently from previous nanotube-based optical devices, which relied on either the optical absorption of semiconducting nanotubes or on the photodesorption of molecular species. In the above described device, the photons are directly absorbed by the polymer, as shown by the fact that devices can be made to respond at different wavelengths by choosing appropriate polymers. The ability to control the spectral response enables devices to be tuned for different applications.

Upon the absorption of a photon, an exciton is generated in the polymer layer. In the polymer matrix without the nanotubes, this exciton would recombine, resulting in the emission of a luminescent photon. In the polymer-nanotube composite fabricated as described herein, the hole is transferred to the nanotube because of the alignment of the nanotube and polymer valence bands. The positive shift in the threshold voltage demonstrated by the composite materials described herein is the first direct electronic evidence for this effect. This shift is similar to that observed when NT-FET devices are exposed to electron withdrawing (hole donating) molecules (e.g., NO2), demonstrating that the photoexcited state of polymer is more electron withdrawing than the ground state.

A complex assembled nanodevice, including separate functional components, has been demonstrated. The device in the embodiments described comprises a light absorber, electrodes, and a composite that, in response to light, leads to charge separation between the components of the composite. The spectral response of the device can be adjusted, by utilizing different polymers with different light absorption characteristics.

### EXAMPLE 2

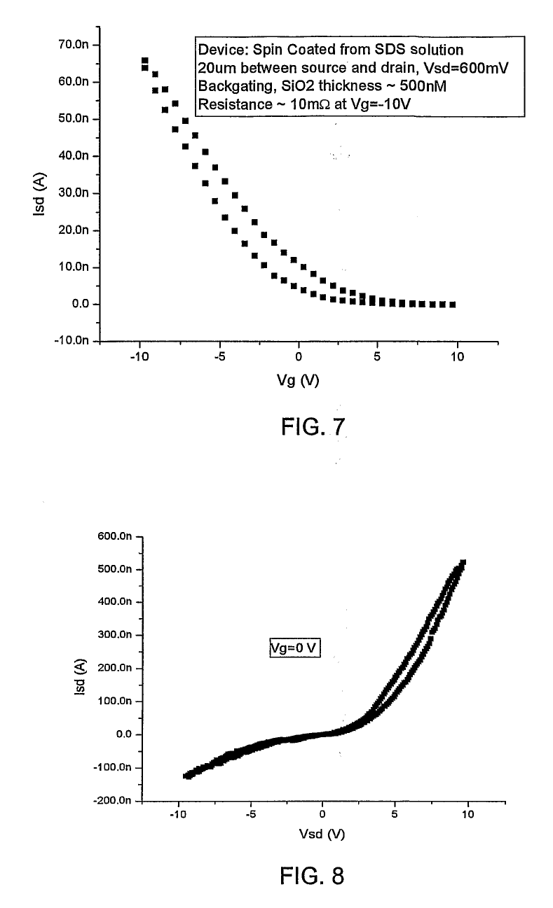

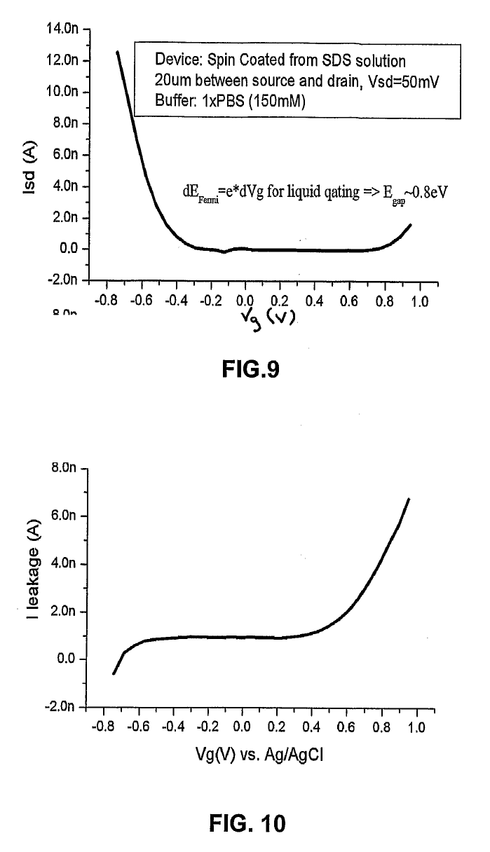

Transistors with carbon nanotube conducting channels were prepared by coating nanotubes with an organic composition. More specifically, carbon nanotubes were added to a solution of SDS (1% sodium dodecyl sulphate and 99% water) at a concentration of 50 mg/liter of solution. The liquid composition was then deposited onto a Si/SiO2 (500 nm thick) die surface, for example by spin coating, and was dried at room temperature. The resultant film was a random network of nanotubes, with multiple tubes forming ropes, arranged as a network with each nanotube in the network coated with SDS. Source and drain contacts, with a 20 um separation were deposited using standard sputtering techniques, with the nanotube network connecting the source and drain. Devices formed as described operate as transistors. The transconductance shifts to more negative gate voltages indicates electron donation from the SDS coating to the nanotubes within the nanotube/SDS composite. FIGS. 7-10 show the electrical characteristics of the nanotube/SDS composite. While the device has a very high resistance, which can be reduced by improving fabrication techniques, it is an early version that demonstrates a high ON/OFF ratio. The Isd(Vsd) characteristic is linear if Vsd is within 200 mV at Vg=0V and there is no saturation at Vsd from −10V. FIGS. 9 and 10 exhibit similar performance using liquid (replacement of the conventional gate electrode, as shown in FIG. 2, by a conducting liquid)

### EXAMPLE 3

A further active device structure comprises a nanostructure composite forming a layer between a source and drain electrode, one of the electrodes being transparent. In such a configuration, with appropriate composite components light will induce a charge transfer from one component to the second component, such charge separation being the basis of a solar cell operation

A prior example of a light induced charge transfer medium comprises layers of a conducting polymer and C₆₉ molecules (“Photoinduced electron-transfer from a conducting polymer to Buckminster fullerene,” N. S. Sariciftci, L. Smilowitz, A. J. Heeger, F. Wudl, Science 258: 1474-6, 1992, “Plastic Solar Cells” J. C. Brabec et al Adv. Funct. Materials 11, 15 (2001).

Applicant has found that there is a light induced charge transfer between a carbon nanotube network and the polymer component of the composite and the charge separated state has a long lifetime. While the polymer (PmPV) used in this study is not particularly conductive, its conductivity can be increased by blending it with a conducting polymer, such as polyaniline or light activated compounds such as rhodopsin or porphyrine. Alternatively, the polymers used in the C60 based work of Scariciftci or Brabec (Scariciftci, et al, N. S. Sariciftci, L. Smilowitz, A. J. Heeger, F. Wudl, Science 258: 1474-6, 1992, “Plastic Solar Cells” J. C. Brabec et al Adv. Funct. Materials 11, 15 (2001)) namely, arylene-ethyrylene/arlene-vinylene hybrid polymers or similar polymers can be utilized.

The photovoltaic cell is based on the mechanism of photoinduced charge transfer between two layers of materials or between two species inter-dispersed. The most common types of solar cells are based on the photovoltaic effect that occurs when light falling on a two-layer semiconductor material produces a potential difference or voltage, between the two layers. In addition, the solar cell has to incorporate a conducting layer that is transparent to sunlight and can act as an electrode.

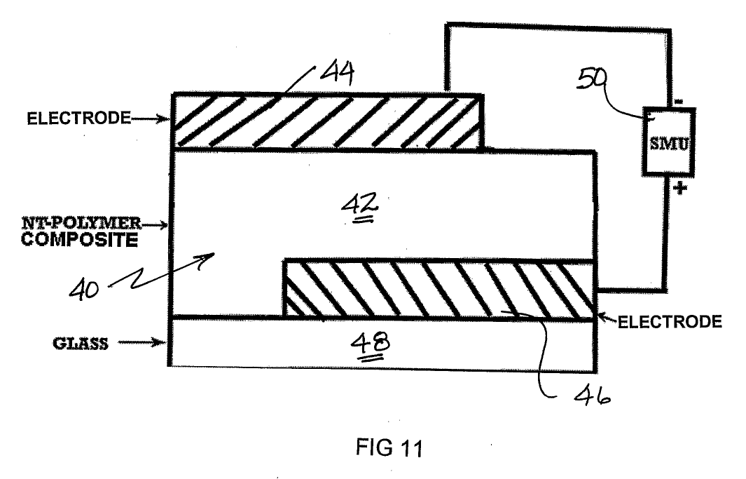

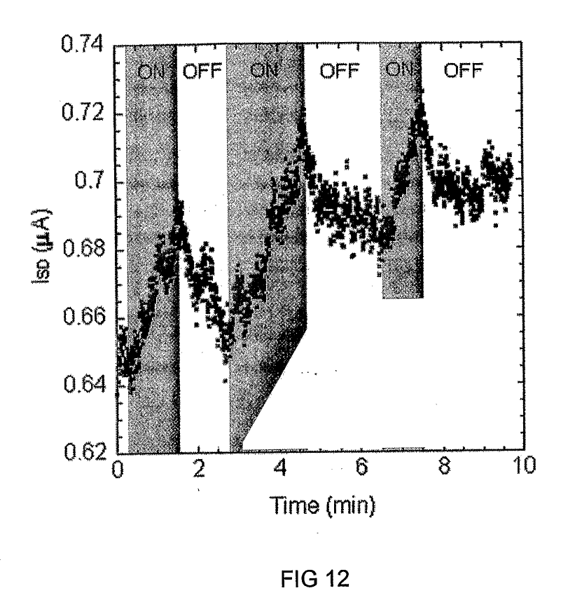

The electronic device in this embodiment is a solar cell that includes a carbon nanotube network/polymer composite, with two electrodes connected to the composite to form the structure. The polymer and the carbon nanotube network are inter-dispersed, forming a composite such as shown in FIG. 1, with the charge transfer occurring between the components of the composite. The composite is incorporated in a solar cell structure schematically shown in FIG. 11. FIG. 12 shows the electrical response of a Pm PV/nanotube composite when exposed to light at 362 nm, with the exposure to light being cycled on and off and at an applied bias of 2V.

The proposed devices have several advantages over the existing devices. They are mechanically robust but flexible so they can be readily used in devices where movement, and particularly vibration, may be encountered. Additionally, they are fault tolerant because of the interconnecting network of conductive nanotubes. The composites, and the subsequent electronic structures produced are readily fabricated, and thus allow the formation of large structures, such as large area solar cells.

While electronic devices utilizing composite active electronic components as described herein have numerous applications they are particularly useful for active matrix flexible displays, solar cells, and sensors, such as light, chemical and biological sensors and radio frequency ID tags (RFID tags). Composites of conductive nano-structure materials in a non-conducting interface have been described. However, the invention also contemplates the fabrication of active electronic devices which incorporate a partially conducting or semi-conducting matrix, such as a carbon nanotube-polyaniline composites, or a doped matrix, which may include, in the same structure, a non-conducting and/or a semi-conducting matrix material. Optoelectronic devices can also be formed where the conducting nano-structure is distributed in a light sensitive matrix, such as PmPV or polymer blends including light activated nmaterials such as porphyrine or rhodopsin, and in particular a semi-conducting matrix, such as PPV blends, parylene blends, conducting polymers such as polyaniline or doped amorphous inorganic materials such as Si.

I claim:

1. An active electronic device comprising a conductive composite having at least two electrodes attached thereto wherein the composite comprises a combination of conductive nanostructures and a second material surrounding said nanostructures.

2. The active electronic device of claim 1 wherein the nanostructure is present as a random network of nanostructures, aligned or partially aligned individual nanostructures or bundles of individual nanostructures or as a mat of nanostructures.

3. The active electronic device of claim 2 where the nonconducting, poorly conducting or semiconducting coating material comprises a coating on all sides of the nanostructure, or on all nanostructures in a bundle or a mat of nanostructures.

4. The active electronic device of claim 3 comprising diodes, field effect transistors, optoelectronic devices or devices which function as a result of a charge transfer between the two elements of the composite.

5. The active electronic device of claim 4 wherein the conductive nanostructures comprise nanowires, nanofibres, nanoribbons, nanoplates or nanotubes.

6. The active electronic device of claim 5 wherein said device is a field effect transistor comprising a composite including carbon nanostructures in a nonconducting, poorly conducting or semiconducting coating material, said composite located on a first surface of a nonconducting substrate, said substrate having a source electrode and a drain electrode attached to said first surface, each electrode being in contact with the composite, and a gate electrode applied to the substrate structure.

7. The active electronic device of claim 6 wherein the nonconducting substrate is an inorganic dielectric or a non-conducting polymer

8. The active electronic device of claim 6 where the nonconducting, poorly conducting or semiconducting coating material is a polymer, organic compound, or inorganic material.

9. The active electronic device of claim 5 wherein said device is a diode comprising a first and a second composite, each of the first and second composite including nanostructures in a nonconducting, poorly conducting or semiconducting coating material, the first composite having p-type characteristics and the second composite having n-type characteristics, said composite located on a first surface of a nonconducting substrate, said substrate having a first electrode and a second electrode attached to said first surface, the first electrode being in contact with the first composite and the second electrode being in contact with the second composite, the first electrode and the second electrode functioning as source and drain electrodes.

10. The active electronic device of claim 9 wherein the nonconducting substrate is an inorganic dielectric or a non-conducting polymer

11. The active electronic device of claim 9 where the nonconducting, poorly conducting or semiconducting coating material is a polymer, organic compound, or inorganic material.

12. The active electronic device of claim 5 wherein said device is a optoelectronic device comprising a composite, said composite including carbon nanostructures in a light activated coating material, said composite located on a first surface of a nonconducting substrate, said composite having a first electrode and a second electrode attached thereto in a spaced apart manner, the first electrode and the second electrode functioning as source and drain electrodes, said electrodes also attached to an electronic circuit.

13. The active electronic device of claim 12 wherein the nonconducting substrate is a transparent glass or a transparent polymeric material.

14. The active electronic device of claim 12 where the light activated coating material is a non-conductive or semi-conductor polymer, organic compound, or inorganic material.

15. The active electronic device of claim 11 wherein the polymer is poly{(m-phenylenevinylene)-co-[(2,5-dioctyloxy-p-phenylene)vinylene]} or regioregular poly(3-octylthiophene-2,5-diyl).

16. The active electronic device of claim 12 wherein the polymer includes light activated substituents or conducting polymers blended therein.

17. The active electronic device of claim 16 wherein the polymer includes rhodopsin or porphyrine.

18. The active electronic device of claim 16 wherein the polymer includes a conducting second polymer blended therein.

19. The active electronic device of claim 16 wherein the polymer includes polyanaline blended therein.

20. The active electronic device of claim 1 comprising active matrix flexible displays, solar cells, light, sensors or radio frequency ID tags.

21. The active electronic device of claim 5 where the nonconducting, poorly conducting or semiconducting coating material is an active material such that exposure to light, pressure or heat causes the rearrangement of electrons within the composite.
